(19) United States
(12) Patent Application Publication
(10) Pub. No.: US 2018/0157093 A1
(43) Pub. Date: Jun. 7, 2018

(54) SHIELD CASE AND DISPLAY DEVICE HAVING THE SAME

(71) Applicant: SAMSUNG DISPLAY CO., LTD., Yongin-si (KR)

(72) Inventors: Jae Woo JANG, Yongin-si (KR); Man Soo KIM, Yongin-si (KR); Jae Hyun CHAE, Yongin-si (KR)

(21) Appl. No.: 15/825,712

(22) Filed: Nov. 29, 2017

(30) Foreign Application Priority Data
Dec. 2, 2016 (KR) 10-2016-0163752

(51) Int. Cl. G02F 1/1333; H05K 9/00; H05K 1/14; H05K 1/18; G02F 1/133

(52) U.S. Cl. CPC G02F 1/133308; H05K 9/0054; H05K 9/0081; H05K 1/144; G02F 1/1368; H05K 1/189; G02F 1/13306; G02F 2001/133334; G02F 1/13338

(57) ABSTRACT

A shield case includes: a receiving unit which defines a space in which a circuit board is accommodated, where the receiving unit includes a bottom surface and a plurality of side surfaces extending from the bottom surface; and a flange extending from a side surface of the side surfaces in a direction opposite to the circuit board.

This application claims priority to Korean Patent Application No. 10-2016-0163752, filed on Dec. 2, 2016, and all the benefits accruing therefrom under 35 U.S.C. 119, the content of which in its entirety is herein incorporated by reference.

### BACKGROUND

### 1. Field

Embodiments of the disclosure relate to a shield case and a display device including the shield case.

### 2. Description of the Related Art

A display device typically includes a driving circuit including a driving chip integrated on a printed circuit board to process signals for displaying an image. The driving circuit may emit electromagnetic waves during an operation thereof, and the electromagnetic waves may cause an electromagnetic interference (“EMI”) with an external electronic device. Since the EMI causes malfunction of an electronic device or has undesired influence on human bodies, the EMI is desired to be reduced.

In particular, a display device typically uses a memory that communicates data with the driving circuit to improve the display quality of the display device or increase the operation speed of the display device.

### SUMMARY

In a process of operating a driving circuit and a memory of a display device, electromagnetic waves emitted from the driving circuit and electromagnetic waves emitted from the memory are combined, and therefore, an electromagnetic interference (“EMI”) may be further increased. Accordingly, it is desired to reduce the EMI by blocking the emission of electromagnetic waves from the driving circuit.

Embodiments relate to a shield case that reduces EMI by blocking the emission of electromagnetic waves.

Embodiments relate to a display device including the shield case.

According to an embodiment of the disclosure, a shield case includes: a receiving unit which defines a space in which a circuit board is accommodated, where the receiving unit includes a bottom surface and a plurality of side surfaces extending from the bottom surface; and a flange extending from a side of the side surfaces in a direction opposite to the circuit board.

In an embodiment, the flange may be parallel to the bottom surface.

In an embodiment, a height of the side surface, from which the flange extends, may be greater than a height of another side surface among the side surfaces.

In an embodiment, the shield case may include a metallic material.

According to another embodiment of the disclosure, there is provided a display device includes: a display panel which displays an image; a touch sensor disposed on a surface of the display panel; a housing which accommodates the display panel therein; a mold frame which supports the display panel and the touch sensor; a driving circuit board connected to one side of the display panel, where the driving circuit board provides an image signal to the display panel; and a shield case fixed to the outside of the housing, where the shield case supports the touch sensor and covers the driving circuit board. In such an embodiment, the shield case includes: a receiving unit which defines a space in which the driving circuit board is accommodated, where the receiving unit includes a bottom surface and a plurality of side surfaces extending from the bottom surface; and a flange bent extending from a side surface of the side surfaces of the receiving unit in a direction opposite to the driving circuit board to support the touch sensor.

In an embodiment, the side surface, from which the flange extends, may correspond to the side of the display panel, which is connected to the driving circuit board.

In an embodiment, the display device may further include a flexible circuit board which connects the driving circuit board to the display panel, and the flexible circuit board may be bent such that the driving circuit board is disposed at an outside of the housing.

In an embodiment, the side surface, from which the flange extends, may be disposed at an outside of the mold frame and the housing.

In an embodiment, the display device may further include a first bonding tape disposed between the mold frame and the display panel.

In an embodiment, the display device may further include: a second bonding tape disposed between the mold frame and the touch sensor; and a third bonding tape disposed between the flange and the touch sensor.

In an embodiment, the second bonding tape and the third bonding tape may have a predetermined elasticity.

In an embodiment, the mold frame may include a synthetic resin having a predetermined insulating property.

In an embodiment, the display device may further include a backlight unit disposed on a surface of the display panel, which is opposite to the surface of the display panel, to provide light to the display panel, where the backlight unit is accommodated in the housing.

In an embodiment, the backlight unit may include: a light source unit which generates light; and a light guide plate which guides the light generated from the light source unit to the display panel.

### BRIEF DESCRIPTION OF THE DRAWINGS

The above and other aspects and features of the disclosure will become more apparent by describing in further detail exemplary embodiments thereof with reference to the accompanying drawings, in which:

FIG. 1 is an exploded perspective view illustrating a display device according to an embodiment of the disclosure;

FIG. 2 is a cross-sectional view illustrating a pixel of a display panel shown in FIG. 1;

FIG. 3 is a cross-sectional view taken along line I-I′ of the display device shown in FIG. 1;

FIG. 4 is a cross-sectional view taken along line II-IP of the display device shown in FIG. 1; and

FIG. 5 is a perspective view illustrating a shield case shown in FIG. 1.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first”, “second”, etc. may be used herein to describe various elements, components, regions, layers and/or sections, these elements should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of the disclosure will be described in detail with reference to the accompanying drawings.

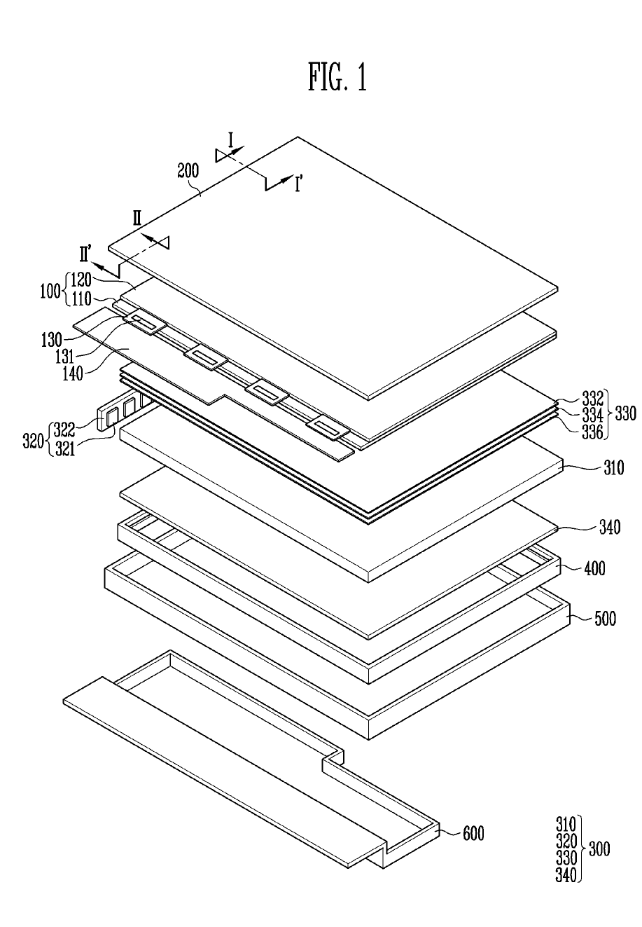

FIG. 1 is an exploded perspective view illustrating a display device according to an embodiment of the disclosure.

Referring to FIG. 1, an embodiment of the display device may include a display panel 100, a touch sensor 200, a backlight unit 300, a mold frame 400, a housing 500, and a shield case 600.

The display panel 100 may have one of various shapes. In one embodiment, for example, the display panel 100 may be in the shape of a closed-shape polygon including linear sides. In an alternative embodiment, the display panel 100 may have one of other various shapes such as a circle, an ellipse, etc., including curved sides. In an embodiment, the display panel 100 may have one of various shapes such as a semicircle, a semi-ellipse, etc., including linear and curved sides. In an embodiment of the disclosure, the display panel 100 has linear sides, and at least one of corners may be curved or rounded. In one embodiment, for example, the display panel 100 has a substantially rectangular shape, at least one vertex or corner of which is curved with a predetermined curvature. In such an embodiment, a vertex portion of the rectangular shape may be formed with a curved side having both adjacent ends respectively connected to two adjacent linear sides, where the curved side has a predetermined curvature. In such an embodiment, the curvature may be differently set depending on positions. In one embodiment, for example, the curvature may be changed depending on a position at which the curve is started, a length of the curve, etc. Hereinafter, for convenience of description, an embodiment where the display panel 100 has a quadrangular shape will be described in detail, but not being limited thereto.

The display panel 100 may be any one of an organic light emitting display (“OLED”) panel, a liquid crystal display (“LCD”) panel, an electrophoretic display (“EPD”) panel, and an electrowetting display (“EWD”) panel, for example. Among such display panels, the OLED panel is a self-luminescent display panel, and the LCD panel, the EPD panel and the EWD panel are non-luminescent display panels. Therefore, in an embodiment, where the display panel 100 is the OLED panel, the backlight unit 300 may be omitted. Hereinafter, for convenience of description, an embodiment where the display panel 100 is the LCD panel will be described in detail, but not being limited thereto.

The display panel 100 may include a display region in which an image is displayed and a non-display region at the periphery of the display region. In an embodiment, the display panel 100 may include a first substrate 110, a second substrate 120 opposite to the first substrate 110, and a liquid crystal layer (not shown) disposed between the first substrate 110 and the second substrate 120. In such an embodiment, a polarizing film (not shown) may be attached to opposing surfaces of the display panel 100, i.e., an outer surface of the first substrate 110 and an outer surface of the second substrate 120.

A plurality of pixels (not shown) arranged in a matrix form may be disposed in the display region of the first substrate. In an embodiment, each pixel may include a plurality of sub-pixels, and the sub-pixels may have different colors from each other. In one embodiment, for example, each sub-pixel may have one predetermined color among red, green, blue, cyan, magenta and yellow. Therefore, light emitted from each sub-pixel may have one color among red, green, blue, cyan, magenta, and yellow. In an embodiment, each pixel may include a gate line (not shown), a data line (not shown) intersecting the gate line to be insulated from the gate line, and a pixel electrode (not shown). In an embodiment, each pixel may include a thin film transistor (not shown) electrically connected to the gate line and the data line, the thin film transistor being electrically connected corresponding to the pixel electrode. The thin film transistor may switch a driving signal provided to the corresponding pixel electrode.

A sealing pattern (not shown) that bonds the first substrate 110 and the second substrate 120 to each other may be disposed in the non-display region of the first substrate. The sealing pattern may be disposed in the non-display region along an edge of the display region.

The second substrate 120 may include a color filter (not shown) disposed on a surface thereof to realize a predetermined color by using light provided from the backlight unit 300 and a common electrode (not shown) disposed on the color filter to face the pixel electrode. In an embodiment, the color filter has one color among red, green, blue, cyan, magenta, and yellow, and may be formed through a process such as deposition or coating. In embodiment, the color filter may be disposed on the second substrate 120 as described above, but the disclosure is not limited thereto. In one alternative embodiment, for example, the color filter may be disposed on the first substrate 110.

As the liquid crystal layer is arranged in a specific direction by an electric field generated between the pixel electrode and the common electrode, the transmittance of the light provided from the backlight unit 300 is controlled, so that the display panel 100 may display an image.

In an embodiment, a signal input pad (not shown) may be disposed in the non-display region on an outer surface of the first substrate 110 or on an outer surface of the second substrate 120. The signal input pad may be connected to a flexible circuit board 130 including a driver integrated circuit (“IC”) 131 disposed, e.g., mounted, on a surface thereof, and the flexible circuit board 130 may be connected to a driving circuit board 140.

The flexible circuit board 130 may allow the driving circuit board 140 and the display panel 100 to be electrically connected to each other. The driver IC 131 may receive various control signals input from the driving circuit board 140, and output a driving signal for driving the display panel 100 to the display panel 100. The flexible circuit board 130 may be bent to allow the driving circuit board 140 to be disposed at an outside of the housing 500.

A plurality of electronic components (not shown) that generate driving and control signals of the display panel 100 may be disposed, e.g., mounted, on the driving circuit board 140. The driving circuit board 140 may be supplied with power from the outside to generate the control signal. In such an embodiment, a majority of the electronic components mounted on the driving circuit board 140 may be operated by a high frequency signal, and generate an electromagnetic wave during the operation. The electromagnetic wave may interfere with the high frequency signal. The interference between the electromagnetic wave and the high frequency signal may be an electromagnetic interference (“EMI”) phenomenon. Therefore, in such an embodiment, a method of grounding the driving circuit board 140 to the housing 500, the shield case 600 or the like may be used.

The touch sensor 200 may be disposed on the display panel 100. In one embodiment, for example, the touch sensor 200 may be disposed on the surface of the display panel, on which an image is implemented.

The touch sensor 200 may include a plurality of sensing electrodes (not shown). The touch sensing electrodes may be arranged in one of various forms, based on ways in which the touch sensor 200 senses a touch.

In one embodiment, for example, some of the touch sensing electrodes may constitute a plurality of touch sensing electrode rows that are connected in one direction and are parallel to each other. In such an embodiment, the others of the touch sensing electrodes may constitute a plurality of touch sensing electrode columns that are connected in a direction intersecting the touch sensing electrode rows and are parallel to each other. In an embodiment, the touch sensor 200 may sense a touch position by measuring a change in capacitance between the touch sensing electrode rows and the touch sensing electrode columns. In such an embodiment, the touch sensor 200 may be a mutual capacitance touch screen type touch sensor.

In an embodiment, the touch sensing electrodes may be arranged in a matrix form, and the touch sensor 200 may sense a touch position by measuring a change in capacitance of each touch sensing electrode. In such an embodiment, the touch sensor 200 may be a self-capacitance touch screen type touch sensor.

The backlight unit 300 is disposed, from the display panel 100, in a direction opposite to a direction to which an image is emitted from the display panel 100. The backlight unit 300 may include a light guide plate 310, a light source unit 320 including a plurality of light sources, an optical member 330, and a reflective sheet 340.

The light guide plate 310 may be disposed under the display panel 100, and guide light emitted from the light source unit 320 to allow the light to be emitted in a direction toward the display panel 100. In an embodiment, the light guide plate 310 may include an emission surface from which the light is emitted, a bottom surface opposite to the emission surface, and side surfaces connecting the emission surface and the bottom surface to each other. In such an embodiment, a side surface of the side surfaces may be an incident surface that faces the light source unit 320 and allows light emitted from the light source unit 320 to be incident thereto, and a side surface opposite to the incident surface may be a reflective surface that allows light to be reflected thereby.

The light source unit 320 may include a plurality of light sources 321 and a printed circuit board 322. The light sources 321 may be light emitting diodes, and be disposed, e.g., mounted, on the printed circuit board 322. In such an embodiment, all of the light sources 321 may emit light of a same color. In one embodiment, for example, the light sources 321 may emit white light.

In an alternative embodiment, the light sources may emit light of different colors. In one embodiment, for example, some of the light sources 321 may emit red light, others of the light sources 321 may emit green light, and the others of the light sources 321 may emit blue light.

The light source unit 320 may be disposed to face at least one of the side surfaces of the light guide plate 310 to emit light thereto, so that light used for the display panel 100 to display an image may be provided through the light guide plate 310.

The optical member 330 may be disposed between the light guide plate 310 and the display panel 100. The optical member 330 may control the light emitted thereto from the light guide plate 310. In an embodiment, the optical member 330 may include a diffusion sheet 336, a prism sheet 334, and a protective sheet 332, which are sequentially stacked one on another.

The diffusion sheet 336 may diffuse light emitted from the light guide plate 310. The prism sheet 334 may condense lights diffused by the diffusion sheet 336 in a direction vertical to the plane of the display panel 100 disposed thereabove. Almost all lights passed through the prism sheet 334 are vertically incident into the display panel 100. The protective sheet 332 may be located on the prism sheet 334. The protective sheet 332 may protect the prism sheet 334 from external impact.

In an embodiment, the optical member 330 includes a single diffusion sheet 336, a single prism sheet 334, and a single protective sheet 332, as shown in FIG. 1, but the disclosure is not limited thereto. In an embodiment, at least one of the diffusion sheet 336, the prism sheet 334 and the protective sheet 332 in the optical member 330 may be folded in plural times, or any one of the diffusion sheet 336, the prism sheet 334 and the protective sheet 332 may be omitted, if desired.

The reflective sheet 340 may be disposed under the light guide plate 310, to change the route of light in the direction toward the display panel 100 by reflecting light in a direction different from the direction toward the display panel 100 and thereby leaked, among lights emitted from the light source unit 320. The reflective sheet 340 may include a material that allows light to be reflected therefrom. The reflective sheet 340 is disposed on the housing 500 to reflect light from the light source unit 320. As a result, the reflective sheet 340 may increase the amount of light provided toward the display panel 100.

In an embodiment, the light source unit 320 is disposed to provide light in a direction toward a side surface of the light guide plate 310, as shown in FIG. 1, but the disclosure is not limited thereto. In one alternative embodiment, for example, the light source unit 320 may be disposed to provide light in a direction toward the bottom surface of the light guide plate 310. In an embodiment, the light guide plate 310 may be omitted in the backlight unit 300, or the light source unit 320 may be disposed under the display panel 100, so that light emitted from the light sources 321 may be directly provided to the display device 100.

The mold frame 400 may have a shape corresponding to the display panel 100 and the backlight unit 300. The mold frame 400 may have a shape in which an inner space is defined to accommodate the display panel 100 and the backlight unit 300 therein. The mold frame 400 may include a holding projection disposed along a side wall thereof. The display panel 100 may be disposed, e.g., mounted, on an upper portion of the holding projection. In such an embodiment, the light guide plate 310 may be disposed, e.g., mounted, on a lower portion of the holding projection.

The mold frame 400 may be coupled to the housing 500, to support and fix the display panel 100 and the backlight unit 300 together with the housing 500. The mold frame 400 may include a synthetic resin having an insulating property.

The housing 500 may be disposed under the backlight unit 300. A space may be defined in the housing 500 such that the display panel 100 and the backlight unit 300 may be accommodated in the space of the housing 500. In such an embodiment, the housing 500 accommodates and support the display panel 100 and the backlight unit 300 in the space thereof.

The shield case 600 is disposed at an outside of the housing 500, and may be fixed to the housing 500. The shield case 600 may cover the driving circuit board 140. The shield case 600 may include a metallic material such as aluminum or copper, for example. Thus, in such an embodiment, the shield case 600 may effectively dissipate heat generated from the driving circuit board 140 and shield electromagnetic waves generated from the driving circuit board 140.

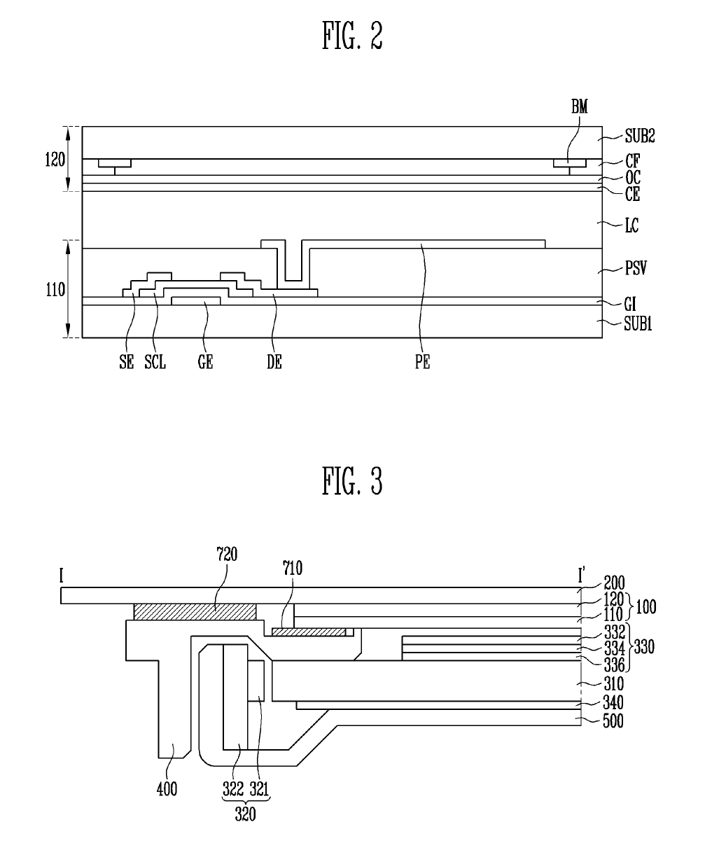

FIG. 2 is a cross-sectional view illustrating a pixel of the display panel shown in FIG. 1.

Referring to FIG. 2, an embodiment of the display panel 100 may include a display region (not shown) and a non-display region (not shown) at the periphery of the display region. In such an embodiment, the display region may include a plurality of pixel regions arranged in a matrix form.

The display panel 100 may include a first substrate 110, a second substrate 120 opposite to the first substrate 110, and a liquid crystal layer LC disposed between the first substrate 110 and the second substrate 120.

The first substrate 110 may include a first base substrate SUB1, a thin film transistor disposed on the first base substrate SUB1, a protective layer PSV covering the thin film transistor, and a first electrode PE connected to the thin film transistor.

The first base substrate SUB1 may include a transparent insulating material to enable light to be transmitted therethrough. In an embodiment, the first base substrate SUB1 may be a rigid substrate. In one embodiment, for example, the first base substrate SUB1 may be one of a glass substrate, a quartz substrate, a glass ceramic substrate and a crystalline glass substrate. In an alternative embodiment, the first base substrate SUB1 may be a flexible substrate. In such an embodiment, the first base substrate SUB1 may be one of a film base substrate and a plastic base substrate, including a polymer organic material. In one embodiment, for example, the first base substrate SUB1 may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose and cellulose acetate propionate, for example. However, the material constituting the first base substrate SUB1 may be variously changed. In one alternative embodiment, for example, the first base substrate SUB1 may be made of fiber glass reinforced plastic (“FRP”) or the like.

The thin film transistor may be disposed in the pixel region on the first base substrate SUB1. The thin film transistor may include a gate electrode GE, a semiconductor layer SCL, a source electrode SE, and a drain electrode DE.

The gate electrode GE may be disposed on the first base substrate SUB1, and the gate electrode GE may be connected to a gate line. In one embodiment, for example, the gate electrode GE may be connected to or defined by a protruding portion of the gate line.

A gate insulating layer GI may be disposed between the gate electrode GE and the semiconductor layer SCL. Therefore, the gate insulating layer GI may insulate the gate electrode GE and the semiconductor layer SCL from each other. The gate insulating layer GI may include at least one of silicon oxide (SiOx) and silicon nitride (SiNx).

The semiconductor layer SCL may be disposed on the gate insulating layer GI, and overlap with the gate electrode GE. The semiconductor layer SCL may include one of amorphous silicon (“a-Si”), polycrystalline silicon (“p-Si”), and an oxide semiconductor. In an embodiment, the oxide semiconductor may include at least one of Zn, In, Ga, Sn, and any mixture thereof. In one embodiment, for example, the oxide semiconductor may include indium-gallium-zinc oxide (“IGZO”).

In an embodiment, regions of the semiconductor layer SCL that are connected to the source electrode SE and the drain electrode DE may define source and drain regions into which impurities are doped or injected. A region of the semiconductor layer SCL between the source region and the drain region may be a channel region.

One end of the source electrode SE may be connected to a data line intersecting the gate line. In one embodiment, for example, the source electrode SE may be connected to or defined by a protruding portion of the data line. The other end of the source electrode SE may be connected to an end of the semiconductor layer SCL.

The drain electrode DE may be disposed to be spaced apart from the source electrode SE. One end of the drain electrode DE may be connected to the other end of the semiconductor layer SCL. The other end of the drain electrode DE may be connected to the first electrode PE.

In an embodiment, the thin film transistor may have a bottom gate structure as shown in FIG. 2, but the disclosure is not limited thereto. In one alternative embodiment, for example, the thin film transistor may have a top gate structure.

The protective layer PSV may cover the thin film transistor. An opening is defined through the protective layer PSV to allow the other end of the drain electrode DE to be exposed therethrough.

The protective layer PSV may include at least one of an inorganic protective layer and an organic protective layer. In one embodiment, for example, the protective layer PSV may include an inorganic insulating layer that covers the thin film transistor and an organic insulating layer disposed on the inorganic insulating layer.

The inorganic insulating layer may include at least one of silicon oxide (SiOx) and silicon nitride (SiNx). In one embodiment, for example, the inorganic insulating layer may include a first layer that covers the thin film transistor and includes silicon oxide, and a second layer that is disposed on the first layer and includes silicon nitride.

The organic insulating layer may include an organic insulating material that enables light to be transmitted therethrough. In one embodiment, for example, the organic insulating layer may include at least one of polyacrylate resin, epoxy resin, phenolic resin, polyamide resin, polyimide resin, unsaturated polyester resin, polyphenylene ether resin, polyphenylene sulfide resin, and benzocyclobutene resin.

The first electrode PE may be disposed on the protective layer PSV, and be connected to the other end of the drain electrode DE. In an embodiment, the first electrode PE may include a transparent conductive oxide. In one embodiment, for example, the first electrode PE may include at least one of indium tin oxide (“ITO”), indium zinc oxide (“IZO”), aluminum zinc oxide (“AZO”), gallium doped zinc oxide (“GZO”), zinc tin oxide (“ZTO”), gallium tin oxide (“GTO”), and fluorine doped tin oxide (“FTO”).

The second substrate 120 may be a counter substrate opposite to the first substrate 110. The second substrate 120 may include a second base substrate SUB2, a light blocking pattern BM, a color filter CF, an overcoat layer OC and a second electrode CE.

The second base substrate SUB2 may include a same material as the first base substrate SUB1. In an embodiment, the second base substrate SUB2 may be a rigid or flexible substrate.

The light blocking pattern BM may be disposed on a surface (e.g., an inner surface or a lower surface) of the second base substrate SUB2, e.g., a surface of the second base substrate SUB2 that is opposite to the first substrate 110. The light blocking pattern BM may be disposed corresponding to a boundary of the pixel regions. In such an embodiment, the light blocking pattern BM may effectively prevent light leakage due to misalignment of liquid crystal molecules.

The color filter CF may be disposed on portions of the second base substrate SUB2 exposed by the light blocking pattern BM. The color filter CF may have a color among red, green, blue, cyan, magenta and yellow. The color filter may be disposed corresponding to the pixel region. In an embodiment, the color filter CF is included in the second substrate 120, as shown in FIG. 2, but the disclosure is not limited thereto. In one alternative embodiment, for example, the color filter CF may be included in the first substrate 110.

The overcoat layer OC may cover the color filter CF, and reduce a step difference between the light blocking pattern BM and the color filter CF.

The second electrode CE may be disposed on the overcoat layer OC. The second electrode CE is insulated from the first electrode PE, and may include a same material as the first electrode PE. In an embodiment, the second electrode CE may receive a common voltage applied from an outside. The second electrode CE may be disposed on the surface of the second substrate 120 facing the first substrate 110.

In an embodiment, the second electrode CE is included in the second substrate 120, as shown in FIG. 2, but the disclosure is not limited thereto. In one alternative embodiment, for example, the second electrode CE may be included in the first substrate 110 in a state in which the second electrode CE is insulated from the first electrode PE. In such an embodiment, at least one of the first electrode PE and the second electrode CE may have a shape including a plurality of slits.

The liquid crystal layer LC may include a plurality of liquid crystal molecules. The liquid crystal molecules may be aligned in a specific direction by an electric field generated by the first electrode PE and the second electrode CE, to control the transmittance of light. Thus, the liquid crystal layer LC allows light provided from the backlight unit to be transmitted therethrough, so that the display panel 100 may display an image.

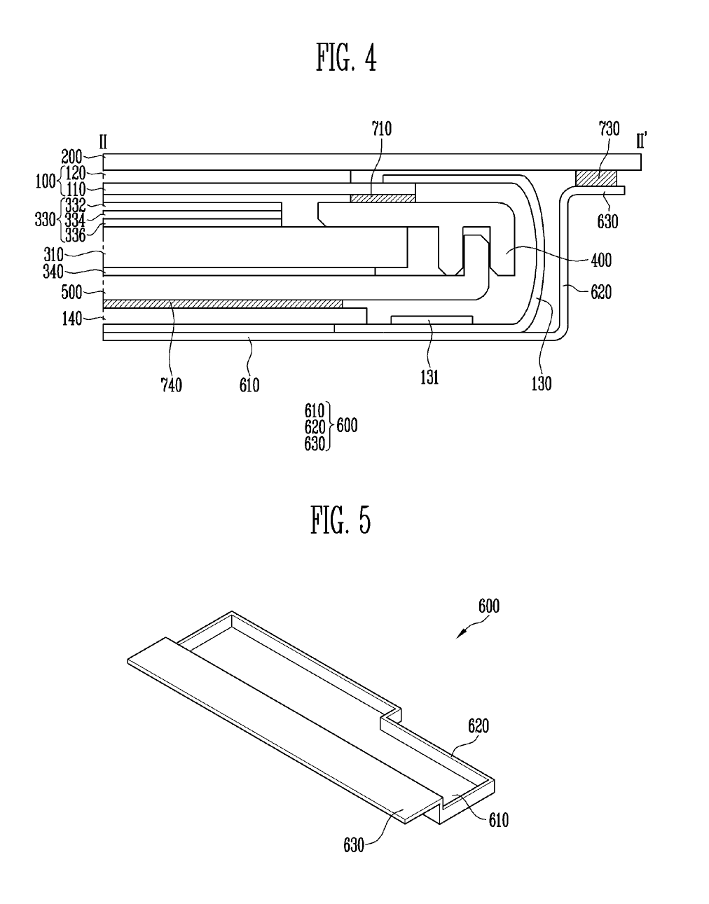

FIG. 3 is a cross-sectional view taken along line I-I′ of the display device shown in FIG. 1. FIG. 4 is a cross-sectional view taken along line II-II′ of the display device shown in FIG. 1. FIG. 5 is a perspective view illustrating the shield case shown in FIG. 1.

Referring to FIGS. 3 to 5, an embodiment of the display device may include a display panel 100, a touch sensor 200, a backlight unit 300, a mold frame 400, a housing 500 and a shield case 600.

The display panel 100 may include a first substrate 110, a second substrate 120 opposite to the first substrate 110, and a liquid crystal layer (not shown) disposed between the first substrate 110 and the second substrate 120.

A driving circuit board 140 that provides a driving signal to the display panel 100 through a flexible circuit board 130 may be connected to a side of the display panel 100. The driving circuit board 140 may be disposed at another outside (e.g., an opposing side) of the housing 500 as the flexible circuit board 130 is bent.

The touch sensor 200 may be disposed on the display panel 100. The touch sensor 200 may sense a touch position corresponding to a touch of a user. The touch sensor 200 may include a plurality of touch sensing electrodes (not shown).

The backlight unit 300 is disposed in a direction opposite to a direction to which an image is output from the display panel 100. The backlight unit 300 may include a light guide plate 310, a light source unit 320 including a plurality of light sources, an optical member 330 and a reflective sheet 340.

The mold frame 400 may include a holding projection to support and to fix the display panel 100 and the backlight unit 300.

Also, the mold frame 400 may include a coupling groove coupled to a portion of the housing 500, e.g., a protruding portion of the housing 500 in the direction of the display panel 100. The mold frame 400 and the housing 500 may be coupled to each other by the coupling groove.

A first bonding tape 710 and a second bonding tape 720 may be disposed on a top surface of the mold frame 400. One of the first bonding tape 710 and the second bonding tape 720, e.g., the first bonding tape 710, may allow the display panel 100 to be fixed to the mold frame 400. In such an embodiment, the first bonding tape 710 may be disposed between the display panel 100 and the mold frame 400, to allow the display panel 100 to be fixed to the mold frame 400.

The other of the first bonding tape 710 and the second bonding tape 720, e.g., the second bonding tape 720, may allow the touch sensor 200 to be fixed to the mold frame 400. In such an embodiment, the second bonding tape 720 may be disposed between the touch sensor 200 and the mold frame 400, to allow the touch sensor 200 to be fixed to the mold frame 400.

The second bonding tape 720 may have a predetermined elasticity, which is determined to absorb pressure or impact generated when the user touches the touch sensor 200.

The second bonding tape 720 may be disposed on the mold frame 400 corresponding to the other sides except a side connected to the driving circuit board 140. In such an embodiment, the second bonding tape 720 may not be provided on the mold frame 400 corresponding to the side connected to the driving circuit board 140.

The housing 500 may include a space in which the display panel 100 and the backlight unit 300 may be accommodated. In such an embodiment, the housing 500 may be coupled to the mold frame 400.

A fourth bonding tape 740 may be disposed on a portion of the outside of the housing 500, e.g., a lower surface of the housing 500, and the driving circuit board 140 may be fixed to the housing 500 through the fourth bonding tape 740. In an embodiment, the driving circuit board 140 may be fixed to the housing 500 through the fourth bonding tape 740 as shown in FIG. 4, but the disclosure is not limited thereto. In an alternative embodiment, the fourth bonding tape 740 may be omitted, and the driving circuit board 140 may be connected to the shield case 600.

The shield case 600 may be disposed at an outside of the housing 500. In one embodiment, for example, the shield case 600 may be disposed under the housing 500. The shield case 600 may cover the driving circuit board 140. The shield case 600 may include or be made of a metallic material such as aluminum or copper. Thus, in such an embodiment, the shield case 600 may effectively dissipate heat generated from the driving circuit board 140 and shield electromagnetic waves generated from the driving circuit board 140.

The shield case 600 may include a receiving unit that defines or provides a space in which the driving circuit board 140 is accommodated, and a flange 630 that supports the touch sensor 200. The receiving unit may include a bottom surface 610 having a shape corresponding to that of the driving circuit board 140, and a plurality of side surfaces 620 bent in a direction of the display panel 100 from the bottom surface 610. The bottom surface 610 and the side surfaces 620 may form a space in which the driving circuit board 140 may be accommodated.

The flange 630 may have a shape bent from a side surface 620 corresponding to a side connected to the driving circuit board 140 of the display panel 100 among the side surfaces 620. In an embodiment, the bent direction of the flange 630 may be a direction opposite to that of the driving circuit board 140. In an embodiment, the flange 630 may be opposite to the touch sensor 200.

The side surface 620 connected to the flange 630 may be disposed at an outside of the mold frame 400 and the housing 500. In an embodiment, the side surface 620 connected to the flange 630 may be exposed to the outside of the display device.

The flange 630 may extend in a direction substantially parallel to the surface of the touch sensor 200, and support the touch sensor 200.

A third bonding tape 730 may be disposed on a top surface of the flange 630, e.g., a surface opposite to the touch sensor 200. In an embodiment, the third bonding tape 730 may be disposed between the flange 630 and the touch sensor 200. The third bonding tape 730 may allow the touch sensor 200 to be fixed to the shield case 600, e.g., the flange 630 of the shield case 600. Thus, in such an embodiment, the touch sensor 200 may be fixed to the mold frame 400 and the shield case 600 by the second bonding tape 720 and the third bonding tape 730.

The third bonding tape 730 may have a predetermined elasticity, which is determined to absorb pressure or impact generated when the user touches the touch sensor 200.

A conventional display device includes only the second bonding tape 720 for fixing the touch sensor 200. That is, the conventional display device does not include a bonding tape corresponding to the third bonding tape. Therefore, as there is a portion at which the touch sensor 200 is not fixed in the conventional display device, movement of the touch sensor 200 may occur.

In an embodiment of the invention, the display device may include not only the second bonding tape 720 but also the third bonding tape 730. The second bonding tape 720 may allow the touch sensor 200 to be fixed to the mold frame 400, and the third bonding tape 730 may allow the touch sensor 200 to be fixed to the flange 630. Thus, the area of a region in which the touch sensor 200 is fixed may be increased, and movement of the touch sensor 200 may be effectively prevented.

According to embodiments of the disclosure, the shield case reduces EMI, and supports the touch sensor through the bonding tape on the flange. Accordingly, in such embodiment, the display device having the shield case may effectively prevent movement of the touch sensor.

Exemplary embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A shield case comprising:
a receiving unit which defines a space in which a circuit board is accommodated, wherein the receiving unit comprises:
a bottom surface; and
a plurality of side surfaces extending from the bottom surface; and
a flange extending from a side of the side surfaces in a direction opposite to the circuit board.

2. The shield case of claim 1, wherein the flange is parallel to the bottom surface.

3. The shield case of claim 1, wherein a height of the side surface, from which the flange extends, is greater than a height of another side surface among the side surfaces.

4. The shield case of claim 1, wherein the shield case comprises a metallic material.

5. A display device comprising:
a display panel which displays an image;
a touch sensor disposed on a surface of the display panel;
a housing which accommodates the display panel therein;
a mold frame which supports the display panel and the touch sensor;
a driving circuit board connected to a side of the display panel, wherein the driving circuit board provides an image signal to the display panel; and
a shield case fixed to the outside of the housing, wherein the shield case supports the touch sensor and covers the driving circuit board,
wherein the shield case comprises:
a receiving unit which defines a space in which the driving circuit board is accommodated, wherein the receiving unit comprises a bottom surface, and a plurality of side surfaces extending to the display panel from the bottom surface; and
a flange extending from a side surface of the side surfaces of the receiving unit in a direction opposite to the driving circuit board to support the touch sensor.

6. The display device of claim 5, wherein the flange is parallel to the touch sensor.

7. The display device of claim 5, wherein the side surface, from which the flange extends, corresponds to the side of the display panel, which is connected the driving circuit board.

8. The display device of claim 7, wherein a height of the side surface, from which the flange extends, is greater than a height of another side surface among the side surfaces.

9. The display device of claim 8, further comprising:
a flexible circuit board which connects the driving circuit board to the display panel
wherein the flexible circuit board is bent such that the driving circuit board is disposed at an outside of the housing.

10. The display device of claim 9, wherein the side surface, from which the flange extends, is disposed at an outside of the mold frame and the housing.

11. The display device of claim 7, further comprising:
a first bonding tape disposed between the mold frame and the display panel.

12. The display device of claim 7, further comprising:
a second bonding tape disposed between the mold frame and the touch sensor; and
a third bonding tape disposed between the flange and the touch sensor.

13. The display device of claim 12, wherein the second bonding tape and the third bonding tape have a predetermined elasticity.

14. The display device of claim 7, wherein the mold frame comprises a synthetic resin having a predetermined insulating property.

15. The display device of claim 7, wherein the shield case comprises a metallic material.

16. The display device of claim 5, further comprising:
a backlight unit disposed on a surface of the display panel, which is opposite to the surface of the display panel, to provide light to the display panel,
wherein the backlight unit is accommodated in the housing.

17. The display device of claim 16, wherein the backlight unit comprises:
a light source unit which generates light; and
a light guide plate which guides the light generated from the light source unit to the display panel.
